(19) United States
(12) Patent Application Publication
(10) Pub. No.: US 2014/0124782 A1
(43) Pub. Date: May 8, 2014

(54) IMAGE SENSOR

(71) Applicant: Samsung Electronics Co., Ltd., Suwon-Si (KR)

(72) Inventors: Jung-kyu JUNG, Seoul (KR); Taeyon LEE, Seoul (KR); Yoondong PARK, Osan-si (KR); Hyunseok LEE, Hwaseong-si (KR)

(73) Assignee: SAMSUNG ELECTRONICS CO., LTD., Suwon-Si (KR)

(21) Appl. No.: 14/073,079

(22) Filed: Nov. 6, 2013

(30) Foreign Application Priority Data
Nov. 6, 2012 (KR) 10-2012-0124944

(51) Int. Cl. H01L 31/02; H01L 31/032

(52) U.S. Cl. CPC H01L 31/02019; H01L 31/0324
USPC 257/48

(57) ABSTRACT

An image sensor may include a first layer on a substrate and including a chalcogenide-containing material, and a detection part connected to the first layer and configured to detect a variation in electric characteristics of the first layer. The chalcogenide-containing material may include one of AₓB_{y}S_{1-x-y}, AₓB_{y}Te_{1-x-y}, and AₓB_{y}Se_{1-x-y}, where 0<x<1, 0<y<1, A may include at least one of Si, Ge, Sn, Pb, Al, Ga, In, Cu, Zn, Ag, Cd, Ti, V, Cr, Mn, Fe, Co, and Ni, and B may include at least one of Sb, Bi, As, and P.

### CROSS-REFERENCE TO RELATED APPLICATIONS

This U.S. non-provisional patent application claims priority under 35 U.S.C. §119 to Korean Patent Application No. 10-2012-0124944, filed on Nov. 6, 2012, in the Korean Intellectual Property Office, the entire contents of which are hereby incorporated by reference.

### BACKGROUND

1. Field

Example embodiments of the inventive concepts relate to an image sensor, and in particular, to a semiconductor image sensor.

2. Description of the Related Art

A material with high quantum efficiency is used to improve performance of photoelectric devices, e.g., image sensors, solar cells, and optical signal detectors. For example, in the case of an image sensor for obtaining distance information, a light receiving portion thereof should be configured to detect infrared light having a longer wavelength than visible light. In other words, the light receiving portion needs to have a relatively high optical absorption coefficient for light with a relatively long wavelength. Similarly, to increase a photoelectric conversion efficiency of a device, a light receiving portion of the solar cell should also be configured to have a relatively high optical absorption coefficient for light with a relatively long wavelength.

### SUMMARY

Example embodiments of the inventive concepts provide a high efficient and electro-optically stable image sensor.

According to example embodiments of the inventive concepts, an image sensor may include a substrate, a first layer on the substrate and formed of a chalcogenide-containing material, and a detection part connected to the first layer to detect a variation in electric characteristics of the first layer. The chalcogenide-containing material may include one of AₓB_{y}S_{1-x-y}, AₓB_{y}Te_{1-x-y}, and AₓB_{y}Se_{1-x-y}, where 0<x<1, 0<y<1, A may include at least one selected from the group consisting of Si, Ge, Sn, Pb, Al, Ga, In, Cu, Zn, Ag, Cd, Ti, V, Cr, Mn, Fe, Co, and Ni, and B may include at least one selected from the group consisting of Sb, Bi, As, and P.

In example embodiments, the image sensor may further include an interposition layer between the substrate and the first layer to be in contact with both of the substrate and the first layer.

In example embodiments, the interposition layer may include at least one of a reflection layer, a finite impulse response filter, and an isolation layer.

In example embodiments, the image sensor may further include an anti-reflecting layer on the first layer.

In example embodiments, the first layer may be spaced apart from the substrate.

In example embodiments, a space between the first layer and the substrate may be substantially equivalent to one-fourth a wavelength of an incident light.

In example embodiments, the detection part may be configured to detect a variation in electric resistance of the first layer.

In example embodiments, the image sensor may further include a second layer provided between the substrate and first layer and formed of a material containing doped silicon or doped germanium. The first and second layers may constitute a junction.

In example embodiments, the detection part may be connected to the second layer to detect a variation in electric current between the first and second layers.

In example embodiments, the image sensor may further include an anti-reflecting layer. The substrate may include two surfaces facing each other, the first layer may be provided on one of two surfaces of the substrate, and the anti-reflecting layer may be provided on the other of two surfaces of the substrate.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating an image sensor according to example embodiments of the inventive concepts.

FIGS. 2A and 2B are sectional views illustrating image sensors according to example embodiments of the inventive concepts.

FIGS. 3A and 3B are sectional views illustrating image sensors according to other example embodiments of the inventive concepts.

FIG. 4 is a sectional view illustrating an image sensor according to still other example embodiments of the inventive concepts.

FIG. 5 is a flow chart illustrating a method of fabricating an image sensor according to example embodiments of the inventive concepts.

FIGS. 6A through 9B are plan views and sectional views illustrating a method of fabricating an image sensor according to example embodiments of the inventive concepts.

FIG. 10 is a flow chart illustrating a method of fabricating an image sensor according to example embodiments of the inventive concepts.

FIGS. 11A through 16B are sectional views illustrating a method of fabricating an image sensor according to example embodiments of the inventive concepts.

FIG. 17 is a block diagram illustrating an example of electronic systems with an image sensor according to example embodiments of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

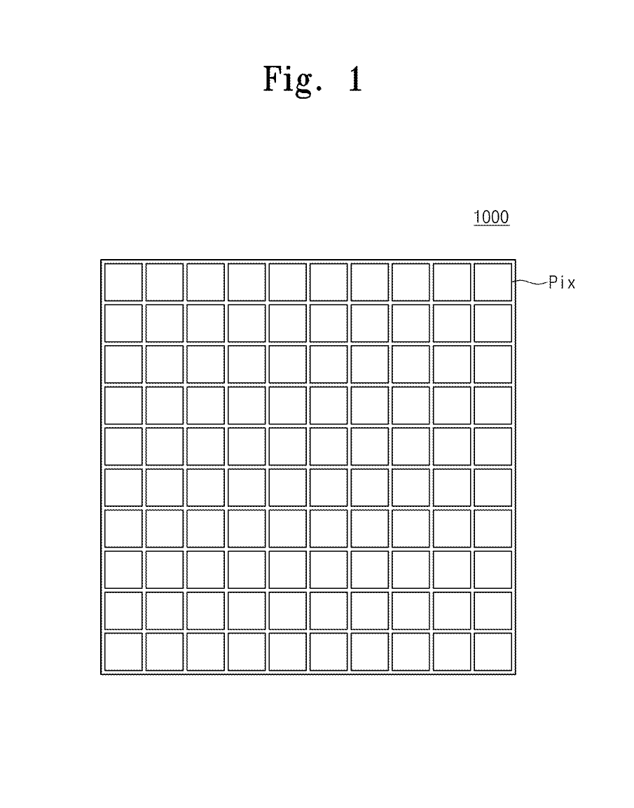

FIG. 1 is a plan view illustrating an image sensor according to example embodiments of the inventive concepts.

Referring to FIG. 1, an image sensor 1000 may include a plurality of pixels Pix. The pixels Pix may be regularly arranged along column and row directions.

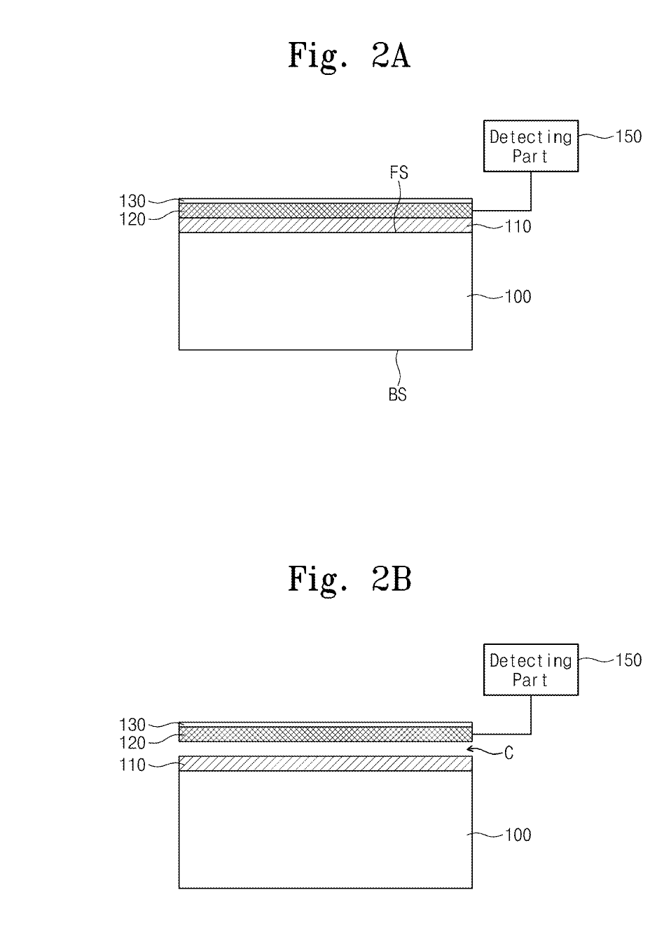

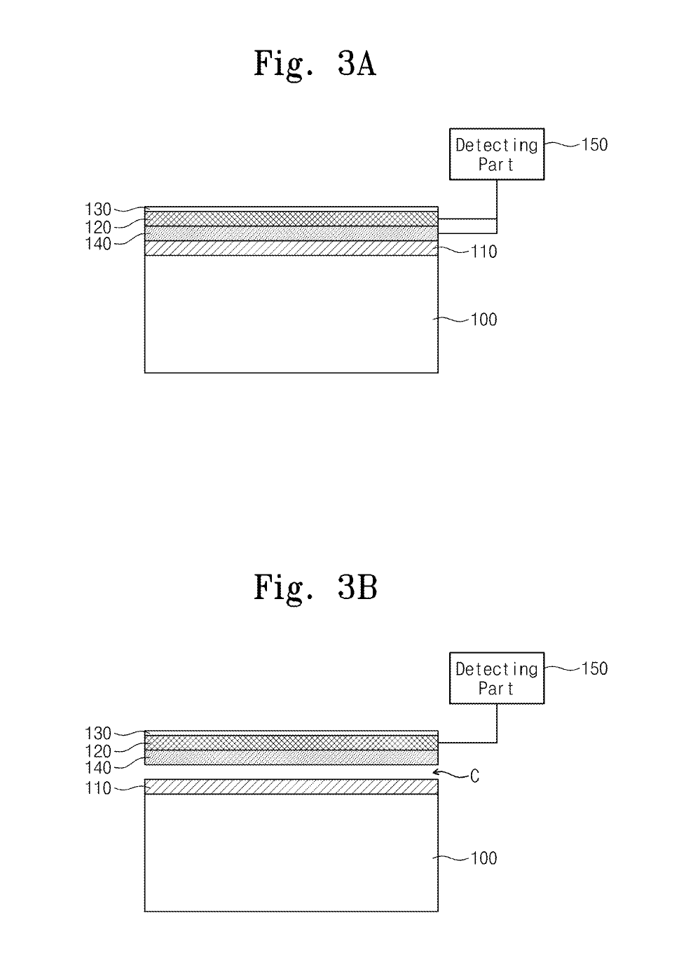

As will be shown in FIG. 2A, the image sensor 1000 may include a front side FS provided with the pixels Pix and a back side BS opposite the front side FS. Although not shown in detail, each of the pixels Pix may include a light sensing portion and a plurality of circuits electrically connected to the light sensing portion.

According to example embodiments of the inventive concepts, the image sensor 1000 may be an infrared light sensing sensor, which will be described below, but example embodiments of the inventive concepts may not be limited thereto. For example, the image sensor 1000 may be configured to sense each or all of visible and ultraviolet lights.

Hereinafter, for the sake of simplicity, the description that follows will refer to one of the pixels Pix of the image sensor 1000.

FIGS. 2A and 2B are sectional views illustrating image sensors according to example embodiments of the inventive concepts. Referring to FIGS. 2A and 2B, the image sensor may include a substrate 100, a layer 120, and a detection part 150. For example, the substrate 100 may include a semiconductor material, e.g., silicon, germanium, or silicon/germanium. Alternatively, the substrate 100 may be configured to include a read out integrated circuit (ROIC).

The layer 120 may be provided on the substrate 100. The layer 120 may include a chalcogenide material. The chalcogenide may be a chemical compound that is a semiconductor or semimetal element in the Group 6A of the periodic table, and may have an outer electron configuration of s²p⁴ or one lone pair and two unpaired electrons, for example, at least one of S, Se, and Te. In an amorphous state, two unpaired electrons are shared by neighboring atoms to form a weakly-bonded chain-like structure. Accordingly, the elements S, Se, and Te may exhibit relatively high temperature coefficient of resistance, relatively low thermal conductivity, and relatively high infrared light absorption property when compared with Si and Ge. The lone pair may be more easily decomposed by environmental, electrical, thermal, and optical factors, and thus, the amorphous chalcogenide can exhibit various material characteristics. According to example embodiments of the inventive concepts, the layer 120 containing chalcogenide may be configured to absorb infrared light having a wavelength of about 8-14 μm and exhibit a change in resistance that is caused by heat generated from the absorbed infrared light.

In example embodiments, the chalcogenide for the layer 120 may include one of AₓB_{y}S_{1-x-y}, AₓB_{y}Te_{1-x-y}, and AₓB_{y}Se_{1-x-y}, where 0<x<1, 0<y<1, A includes at least one of Si, Ge, Sn, Pb, Al, Ga, In, Cu, Zn, Ag, Cd, Ti, V, Cr, Mn, Fe, Co, and Ni, and B includes at least one of Sb, Bi, As, and P.

In example embodiments, the chalcogenide may have resistivity ranging from about 0.05 Ω·cm to about 500 Ω·cm. Further, the chalcogenide may have a crystalline or amorphous structure.

The conventional image sensor may include an absorption layer absorbing infrared light and a conversion layer converting the absorbed infrared light into an electric signal using a photo-thermal effect. By contrast, according to example embodiments of the inventive concepts, the image sensor may include the chalcogenide-containing layer 120 capable of serving as both the absorption layer and the conversion layer. Accordingly, the fabrication process can be simplified and the image sensor can be miniaturized and highly integrated.

Further, in the conventional image sensor, the conversion layer may include an amorphous silicon layer resulting in a larger heat loss for the absorbed infrared light, but according to example embodiments of the inventive concepts, the chalcogenide of the image sensor may exhibit a smaller heat loss for the infrared light compared with the amorphous silicon layer. As a result, the image sensor can have improved reliability.

The detection part 150 may be electrically connected to the layer 120. The detection part 150 may be configured to detect a change in resistance of the chalcogenide-containing layer 120, which may be caused by the incident infrared light or heat generated therefrom.

According to example embodiments of the inventive concepts, the image sensor may further include an anti-reflecting layer 130 provided on the layer 120.

According to example embodiments of the inventive concepts, the image sensor may further include an interposition layer 110 interposed between the substrate 100 and the layer 120. The interposition layer 110 may include at least one of a reflection layer, a finite impulse response filter, and an isolation layer.

According to example embodiments of the inventive concepts, as shown in FIG. 2A, the interposition layer 110 may be provided to be in contact with both the substrate 100 and the layer 120. Accordingly, there is no cavity between the substrate 100 and the layer 120. This absence of a cavity makes it possible to omit steps of vacuumizing a cavity of the conventional image sensor or filling the cavity with inert gas. Accordingly, the fabrication process of the image sensor can be simplified, and the image sensor can be miniaturized and highly integrated. Further, reducing a fabrication cost of the image sensor may be possible.

For example, in the case where the interposition layer 110 may include a reflection layer and an isolation layer, the reflection layer and the isolation layer may be sequentially stacked on the substrate 100 without the cavity. In example embodiments, in order to achieve Fabry-Perot resonance for incident light, the isolation layer may be configured to have a thickness that is equivalent to one-fourth a wavelength of the incident light.

According to example embodiments of the inventive concepts, as shown in FIG. 2B, the interposition layer 110 may be in contact with the substrate 100 and be spaced apart from the layer 120. For example, the cavity C may be formed between the interposition layer 110 and the substrate 100. A space between the interposition layer 110 and the layer 120 may be configured to have a thickness that is equivalent to one-fourth of the wavelength of the incident light. According to example embodiments of the inventive concepts, in the image sensor, the layer 120 may be spaced apart from the substrate 100 without the interposition layer 110 (not shown). In example embodiments, a space between the substrate 100 and the layer 120 may be configured to have a thickness that is equivalent to one-fourth of the wavelength of the incident light.

For example, the cavity C may be in a vacuum state. Alternatively, the cavity C may be filled with a dielectric material having relatively low thermal conductivity. The dielectric material may include at least one of Si—O, Si—N, Ti—O, and Al—O.

FIGS. 3A and 3B are sectional views illustrating image sensors according to example embodiments of the inventive concepts.

Referring to FIGS. 3A and 3B, the image sensor may include a substrate 100, a first layer 140, a second layer 120, and a detection part 150.

The first layer 140 may be provided on the substrate 100 and include a material containing doped silicon or doped germanium. The doped silicon or the doped germanium may contain p- or n-type impurities. The first layer 140 may exhibit various material properties (e.g., a semiconductor property), depending on the type and doping concentration of impurities contained in the doped silicon or the doped germanium.

The second layer 120 may be provided on the first layer 140 to form a junction, and the second layer 120 may include a chalcogenide material. In example embodiments, the chalcogenide for the second layer 120 may include one of AₓB_{y}S_{1-x-y}, AₓB_{y}Te_{1-x-y}, and AₓB_{y}Se_{1-x-y}, where 0<x<1, 0<y<1A, A includes at least one of Si, Ge, Sn, Pb, Al, Ga, In, Cu, Zn, Ag, Cd, Ti, V, Cr, Mn, Fe, Co, and Ni, and B includes at least one of Sb, Bi, As, and P.

In example embodiments, the first and second layers 140 and 120 may be configured to form a hetero junction. The hetero junction may include an anisotype junction, e.g., nP or Np junction, and an isotype junction, e.g., nN or pP junction, where a part denoted by the capital letter N or P has a bandgap larger than that of the other denoted by the small letter n or p.

For example, in the case where the chalcogenide for the second layer 120 is a Ge—Sb—Te based material, the second layer 120 may serve as a p-type semiconductor. The anisotype junction made of the first and second layers 140 and 120 may be configured to have various properties, depending on the type and concentration of impurity contained in the first layer 140. An image sensor optimized or improved to a desired wavelength can be fabricated by adjusting the type and concentration of impurity to be injected into silicon or germanium of the first layer 140.

The first and second layers 140 and 120 constituting the anisotype junction may serve as a photo diode. If light is incident into the photo diode, electrons and holes are generated to form an electric current. A voltage may be proportional to an intensity of the incident light. As the result of the photoelectric effect, a photoelectro-motive force effect, which may occur at a semiconductor junction, may occur.

The detection part 150 may be electrically connected to the first and second layers 140 and 120. The detection part 150 may be configured to detect a variation in current or voltage in the first and second layers 140 and 120.

In example embodiments, the image sensor may further include an anti-reflecting layer 130 on the second layer 120.

In example embodiments, the image sensor may further include an interposition layer 110 interposed between the substrate 100 and the first layer 140. The interposition layer 110 may include at least one of a reflection layer, a finite impulse response filter, and an isolation layer.

According to example embodiments of the inventive concepts, as shown in FIG. 3A, the interposition layer 110 may be provided to be in contact with both of the substrate 100 and the first layer 140. For example, there is no cavity between the substrate 100 and the first layer 140. This absence of a cavity between the substrate 100 and the first layer 140 makes it possible to omit steps of vacuumizing a cavity of the conventional image sensor or filling the cavity with inert gas. Accordingly, the fabrication process of the image sensor can be simplified, and the image sensor can be miniaturized and highly integrated. Further, reducing a fabrication cost of the image sensor may be possible.

According to example embodiments of the inventive concepts, as shown in FIG. 3B, the interposition layer 110 may be in contact with the substrate 100 and be spaced apart from the first layer 140. A cavity C between the interposition layer 110 and the first layer 140 may be configured to have a thickness that is equivalent to one-fourth of the wavelength of the incident light. According to example embodiments of the inventive concepts, the image sensor may not have the interposition layer 110, and the first layer may be provided spaced apart from the substrate 100. In example embodiments, a cavity between the substrate 100 and the first layer 140 may be one-fourth of the wavelength of the incident light.

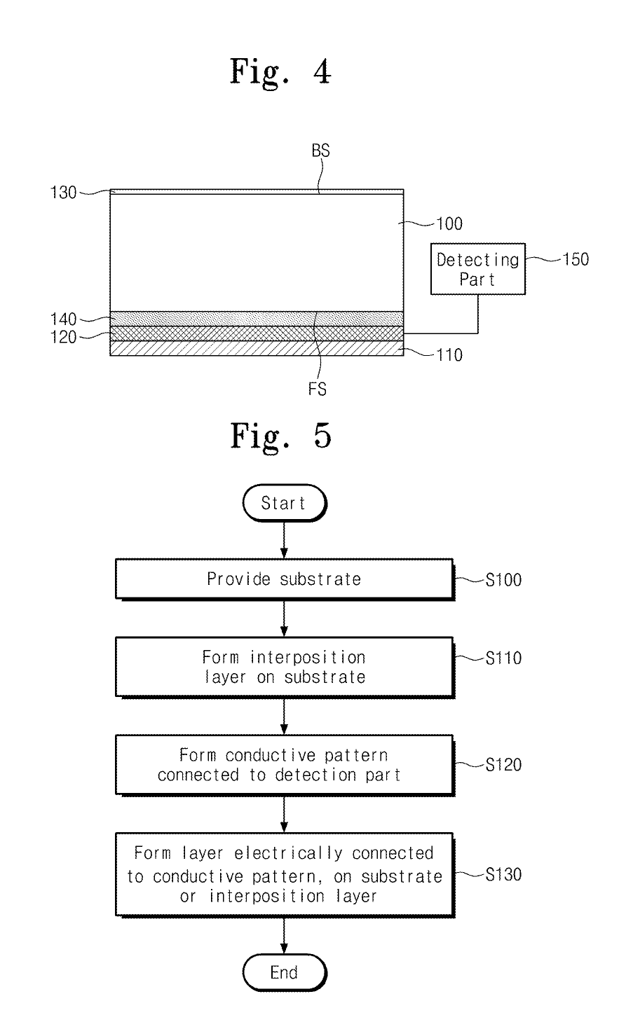

FIG. 4 is a sectional view illustrating an image sensor according to still other example embodiments of the inventive concepts.

Referring to FIGS. 1 and 4, the image sensor may include a substrate 100, a first layer 140, a second layer 120, an interposition layer 110, an anti-reflecting layer 130, and a detection part 150. In example embodiments, the interposition layer 110 may serve as a reflection layer, which will be depicted by the reference numeral 110 in FIG. 4.

The substrate 100 may include a front side FS, where pixels and circuits are formed, and a back side BS facing the front side FS. Referring to FIG. 4, the first and second layers 140 and 120 may be provided on the front side FS, and the reflection layer 110 may be provided on the second layer 120. According to example embodiments of the inventive concepts, although not shown, a finite impulse response filter and an isolation layer may be further provided adjacent to the reflection layer 110. The anti-reflecting layer 130 may be provided on the back side BS of the substrate 100.

According to example embodiments of the inventive concepts, the image sensor may be configured to detect infrared light. In example embodiments, the image sensor may be configured in such a way that light is incident through the back side BS provided with the anti-reflecting layer 130. The incident light may be filtered by the substrate 100 including a semiconductor material (e.g., silicon or germanium), which is placed on a propagation path of the incident light. Thus, a more pure infrared light may be incident into the first and second layers 140 and 120.

Further, in the case where a plurality of circuits are formed on the front side FS of the substrate 100, a light-transmittable area may be smaller when the infrared light is incident through the front side FS of the substrate 100 than when the infrared light is incident through the back side BS of the substrate 100. In other words, when light is incident through the back side BS of the substrate 100, an amount of infrared light may be increased and the image sensor can have improved reliability.

In other example embodiments, the reflection layer 110 may be removed from the second layer 120, and thus, light may be incident into the front and back sides FS and BS of the image sensor.

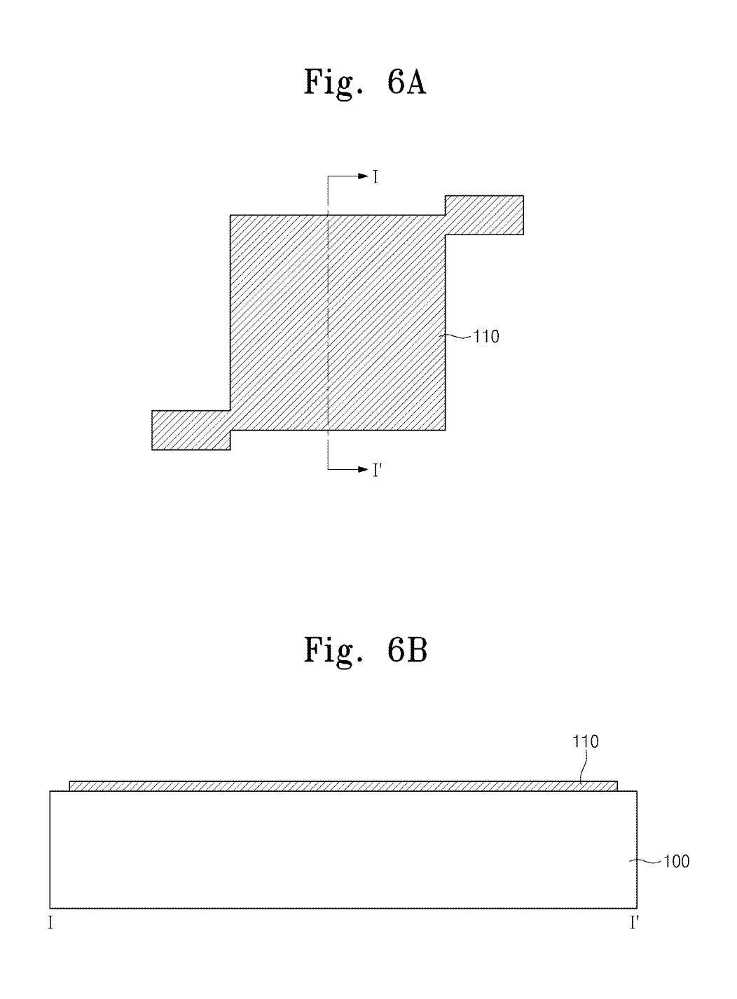

FIG. 5 is a flow chart illustrating a method of fabricating an image sensor according to example embodiments of the inventive concepts. FIGS. 6A, 7A, 8A, and 9A and FIGS. 6B, 7B, 8B, and 9B are plan and sectional views illustrating a method of fabricating an image sensor according to example embodiments of the inventive concepts. FIGS. 6B through 9B are sectional views taken along a line I-I′ of FIGS. 6A through 9A, respectively.

Referring to FIGS. 5, 6A and 6B, a substrate 100 may be provided, and then, an interposition layer 110 may be formed on the substrate 100 (in S100 and S110). The interposition layer 110 may include at least one of a reflection layer, a finite impulse response filter, or an isolation layer.

In example embodiments, referring to FIGS. 6A and 6B, the interposition layer 110 may include metal. As a result, the interposition layer 110 may serve as the reflection layer.

In example embodiments, the interposition layer 110 may be omitted. For example, the formation of the image sensor of FIG. 4 may not include a step of forming the interposition layer 110. Embodiments with the interposition layer 110 will be described below.

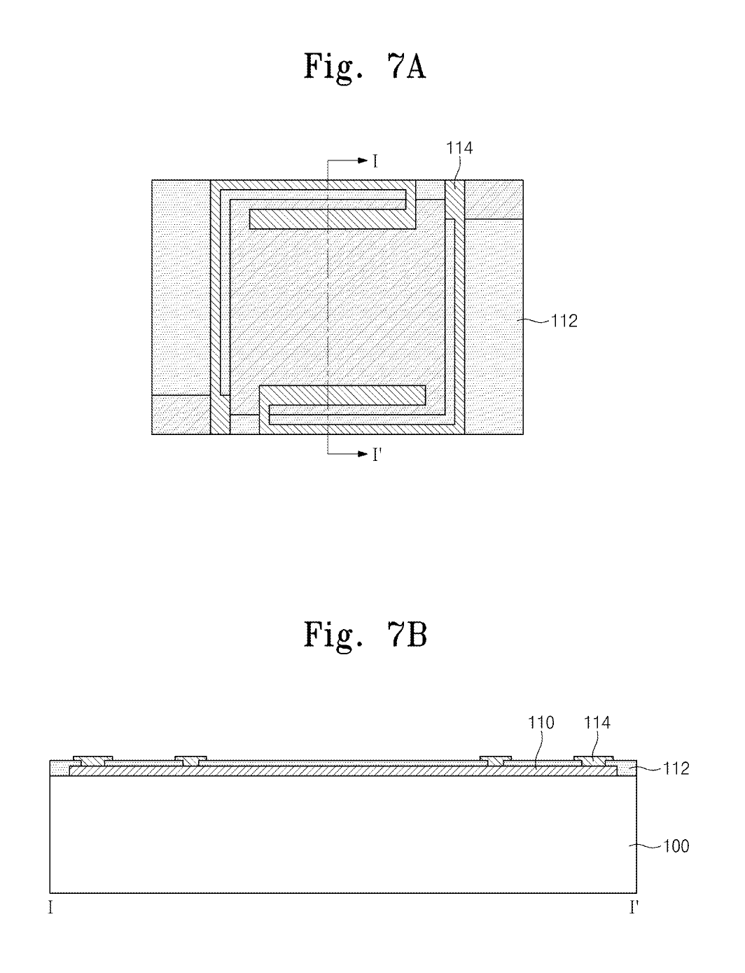

Referring to FIGS. 5, 7A, and 7B, a conductive pattern 114 may be formed on the interposition layer 110 (in S120).

For example, a first insulating layer 112 may be formed on the interposition layer 110 and be patterned to form an opening (not shown) partially exposing the substrate 100. Although not shown in detail, the substrate 100 may include a circuit pattern electrically connected to the detection part 150. The opening may be formed to expose the circuit pattern. The conductive pattern 114 may be formed to fill the opening. As a result, the conductive pattern 114 may be electrically connected to the circuit pattern and the detection part 150.

In example embodiments, in the case where the interposition layer 110 is a metal reflection layer, the opening may be formed to expose partially the interposition layer 110. Although not shown in detail, the substrate 100 may be configured to include a circuit pattern electrically connected to the detection part 150, and the interposition layer 110 may be electrically connected to the circuit pattern. Thereafter, a conductive pattern 114 may be formed to fill the opening. Accordingly, the conductive pattern 114 may be electrically connected to the interposition layer 110 and the detection part 150.

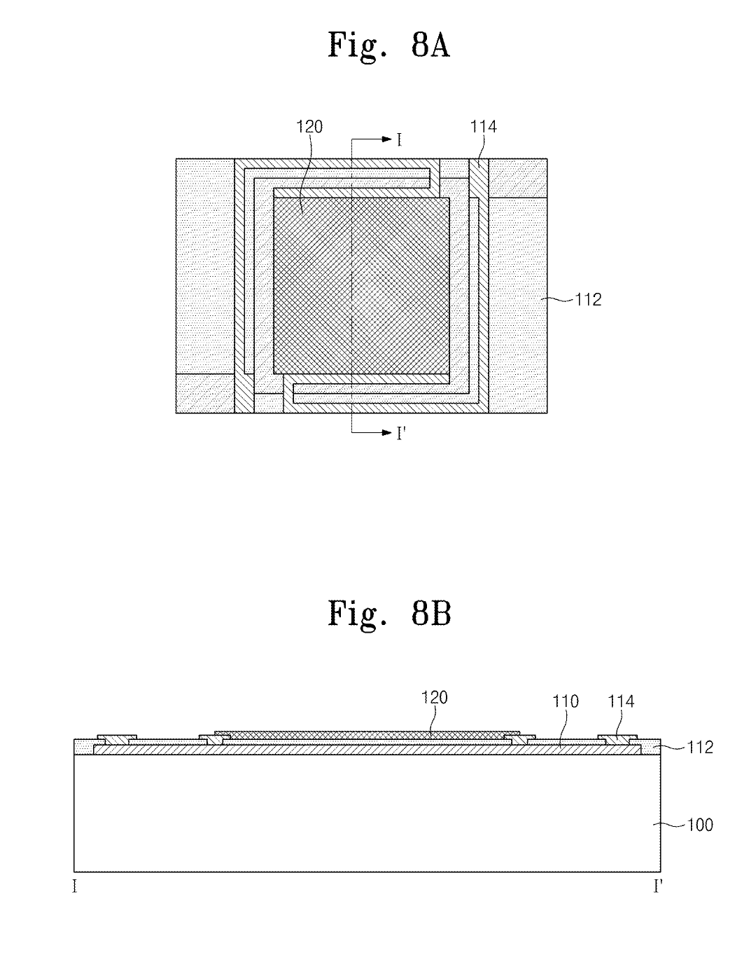

Referring to FIGS. 5, 8A, and 8B, a layer 120 may be formed on the conductive pattern 114 and the first insulating layer 112 (in S130). As shown in FIG. 2A, the layer 120 may be a chalcogenide-containing monolayer. In other example embodiments, as shown in FIG. 3A, the layer may be a dual layer, in which a first layer 140 (containing doped silicon or doped germanium) and a second layer 120 (containing chalcogenide) are configured to form a heterogeneous junction.

According to example embodiments of the inventive concepts, the thickness of the layer 120 may be controlled to realize Fabry-Perot resonance. Further, the thickness of the substrate 100 may be controlled to realize Fabry-Perot resonance.

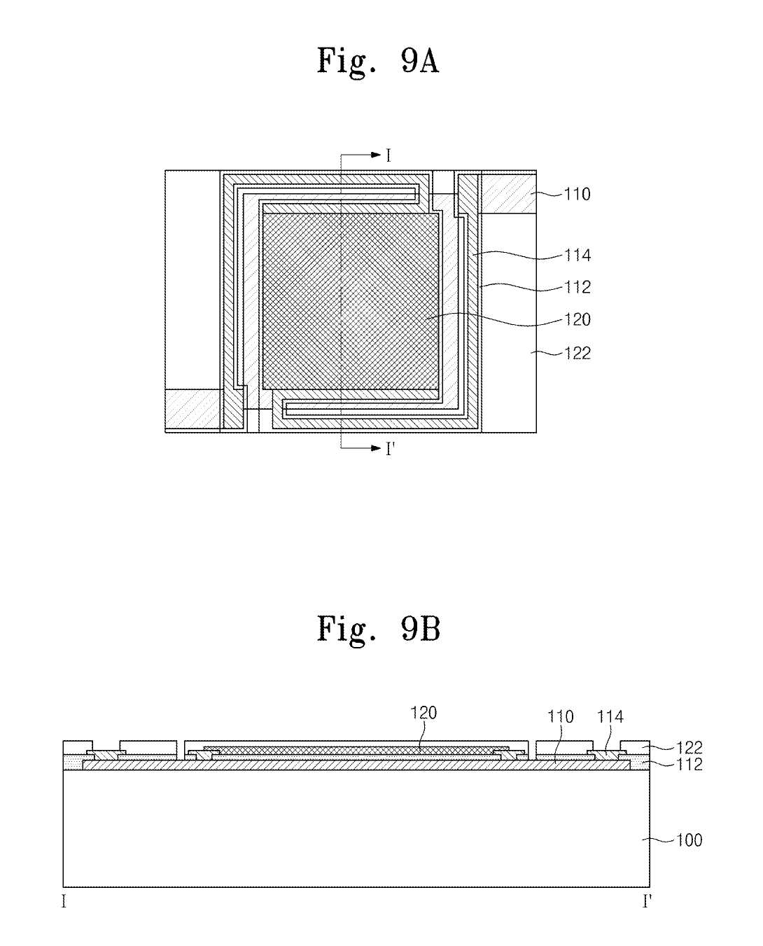

Referring to FIGS. 5, 9A, and 9B, a second insulating layer 122 may be formed on the layer 120, and then, as shown in FIG. 9A, the second insulating layer 122 may be patterned to expose partially the layer 110 and the conductive pattern 114.

As the result of the pattering of the second insulating layer 122, the second insulating layer 122 may be removed from between the layer 110 and the conductive pattern 114. Accordingly, a thermal conduction between the layer 110 and the conductive pattern 144 may decrease. Although not shown in detail, an anti-reflecting layer 130 may be further formed on the second insulating layer 122.

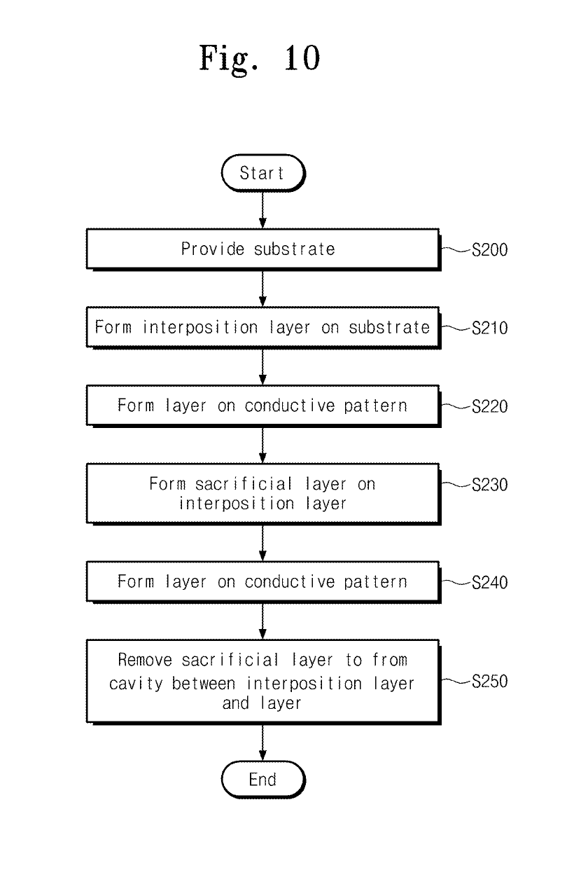

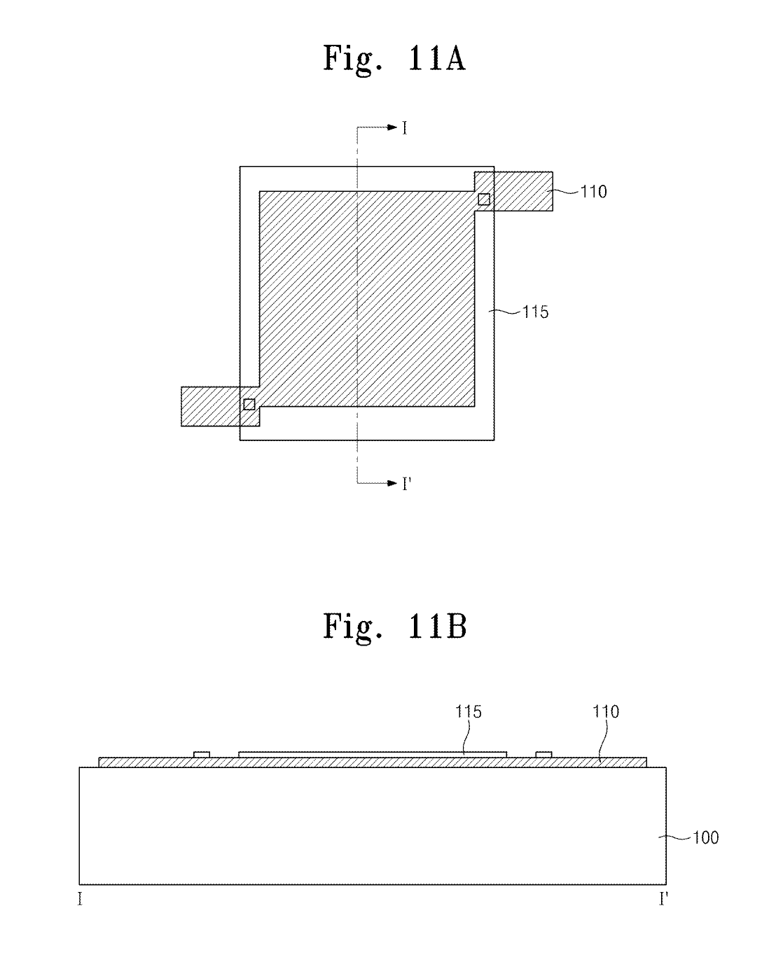

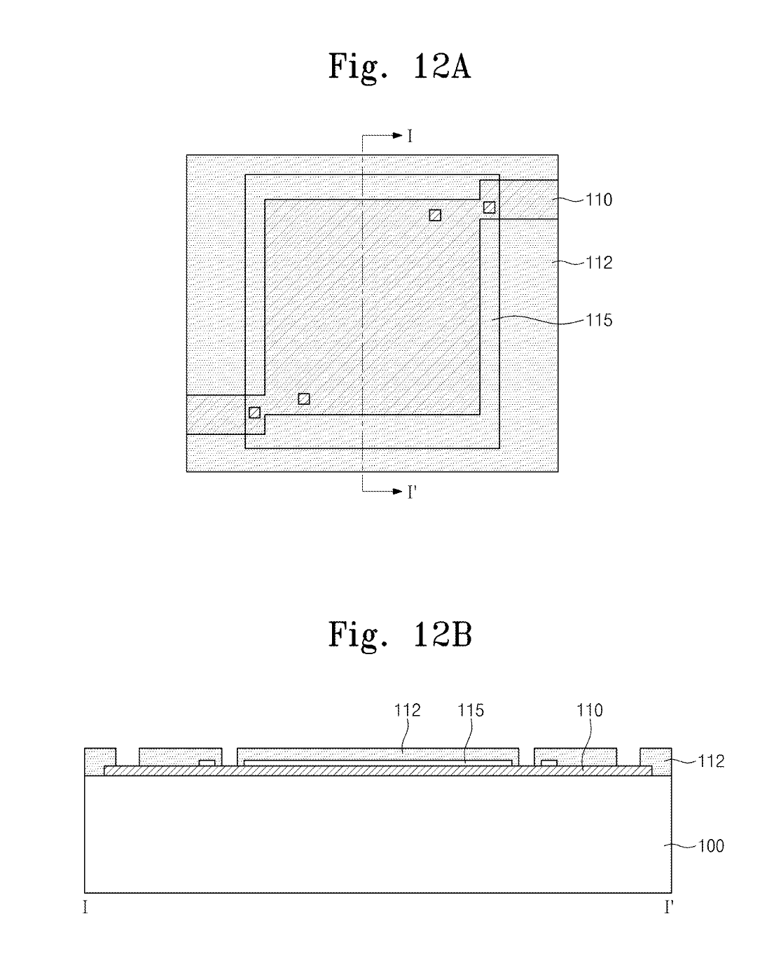

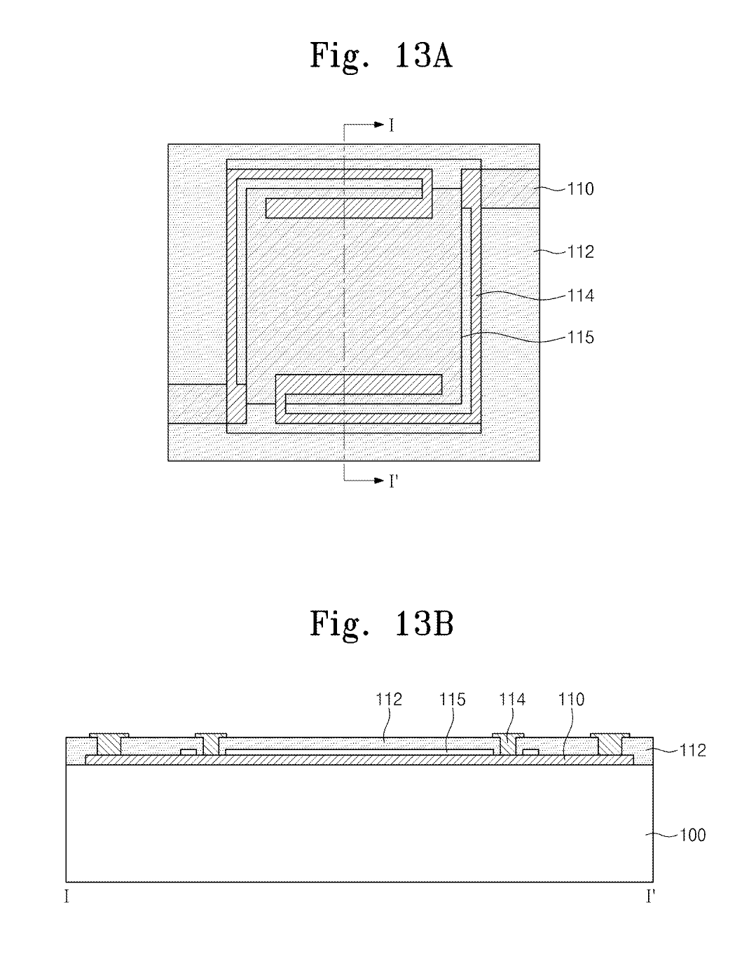

FIG. 10 is a flow chart illustrating a method of fabricating an image sensor according to other example embodiments of the inventive concepts. FIGS. 11A, 12A, 13A, 14A, 15A, and 16A are plan views illustrating a method of fabricating an image sensor according to example embodiments of the inventive concepts, and FIGS. 11B, 12B, 13B, 14B, 15B, and 16B are sectional views illustrating a method of fabricating an image sensor according to example embodiments of the inventive concepts. FIGS. 11B through 15B are sectional views taken along lines I-I′ of FIGS. 11A through 15A, respectively.

Referring to FIGS. 10, 11A, and 11B, an interposition layer 110 may be formed on the substrate 100 (in S200 and S210). The substrate 100 and the interposition layer 110 may be formed to have substantially the same features as that of the previous embodiments described with reference to FIGS. 5, 6A, and 6B, and thus, a detailed explanation of this will be omitted.

A sacrificial layer 115 may be formed on the interposition layer 110 (in S220). The sacrificial layer 115 may include a material having an etch selectivity with respect to the interposition layer 110 as well as a conductive pattern 114 and a layer, which will be formed in a subsequent process. In example embodiments, the sacrificial layer 115 may be formed to have a thickness that is equivalent to one-fourth of a wavelength of the incident light.

Referring to FIGS. 10, 12A, 12B, 13A, and 13B, a first insulating layer 112 may be formed on the sacrificial layer 115 and the conductive pattern 114 may be formed (in S230). This may be performed using substantially the same process as that of the previous embodiments described with reference to FIGS. 5, 7A, and 7B, and thus, a detailed explanation of this will be omitted.

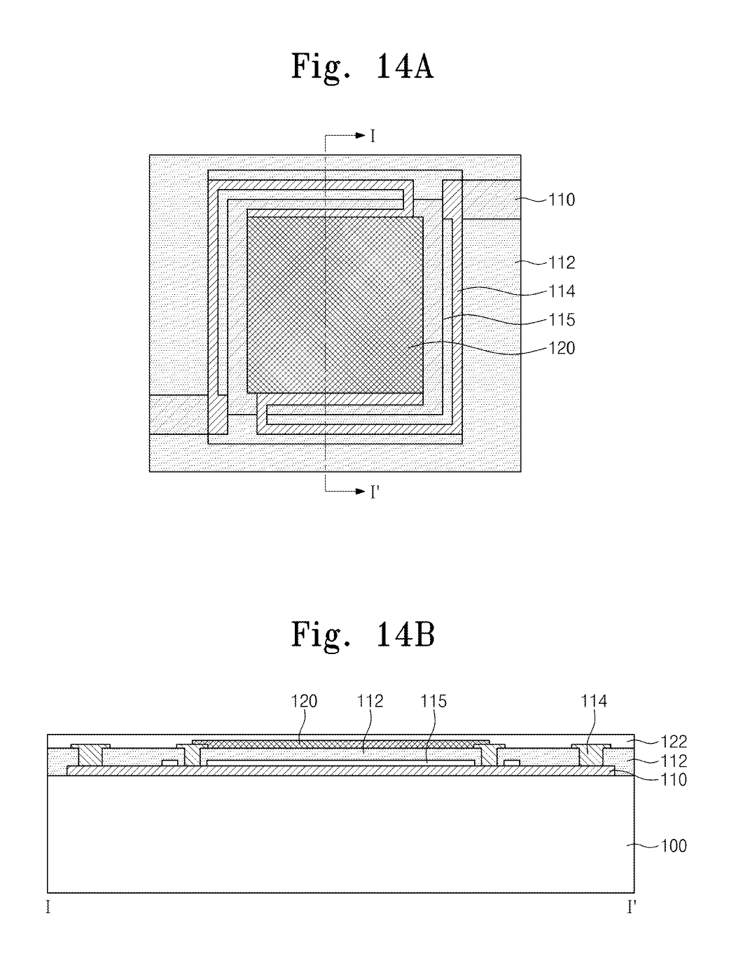

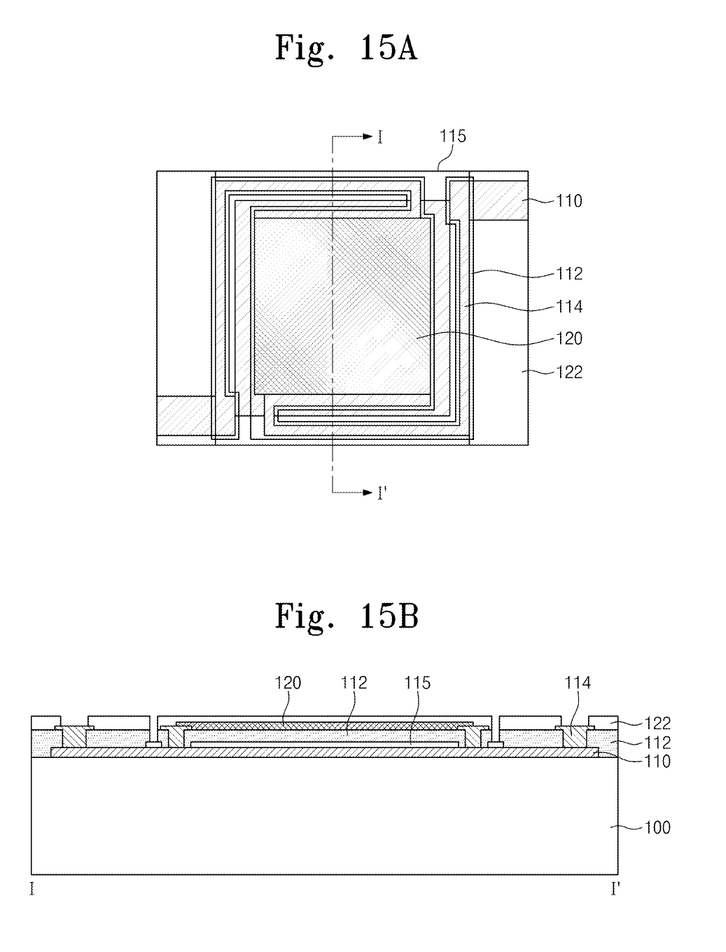

Referring to FIGS. 10, 14A, and 14B, a layer 120 may be formed on the conductive pattern 114 and the first insulating layer 112 (in S240). As shown in FIG. 2B, the layer 120 may be formed to have a single-layered structure containing chalcogenide. As shown in FIG. 3B, the layer may include a first layer 140 (for example, including doped silicon or doped germanium) and a second layer 120 (for example, including chalcogenide). In other words, the layer 120 may be a dual layer having a heterogeneous junction structure. Thereafter, a second insulating layer 122 may be formed on the layer 122.

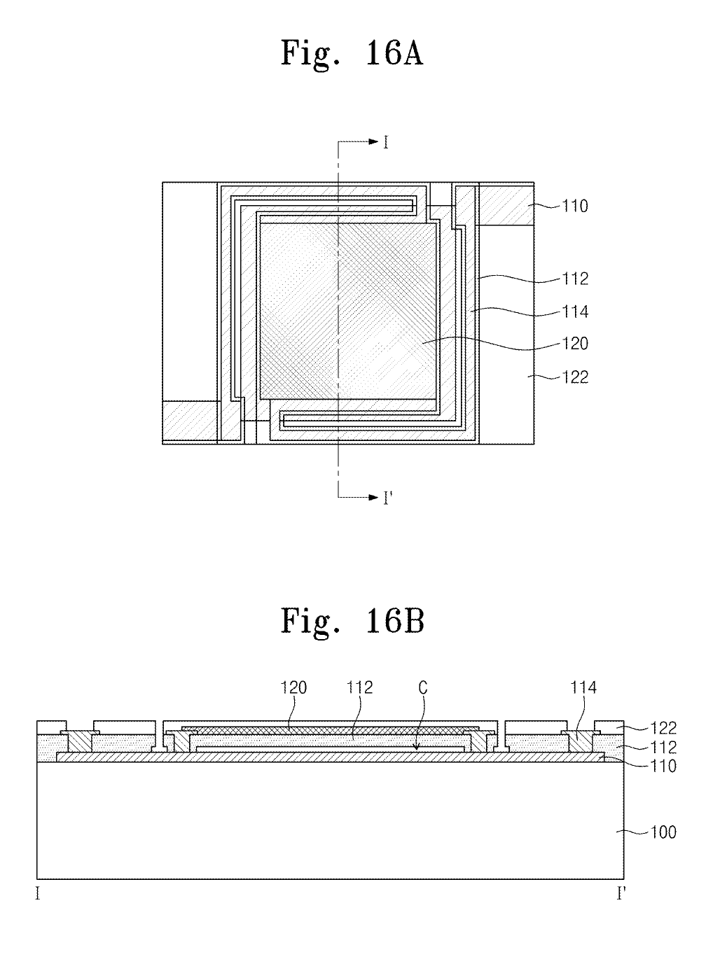

Referring to FIGS. 10, 15A, and 15B, the second insulating layer 122 may be patterned to expose the sacrificial layer 115. Referring to FIGS. 10, 16A, and 16B, the exposed sacrificial layer 115 may be removed to form a cavity C between the interposition layer 110 and the layer (in S250).

Hereinafter, two methods of fabricating an image sensor were described, but example embodiments of the inventive concepts may not be limited thereto.

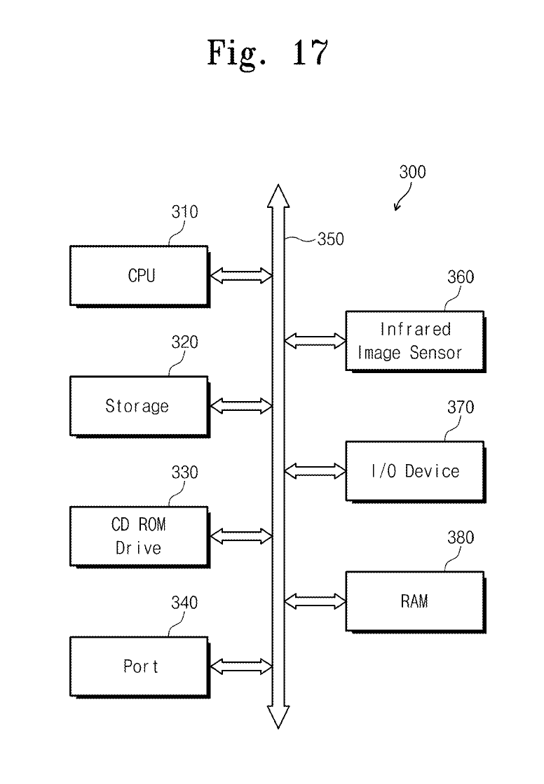

FIG. 17 is a block diagram illustrating an example of electronic systems with an image sensor according to example embodiments of the inventive concepts.

Referring to FIG. 17, a system 300 may include an infrared image sensor 360. The system 300 may be or include a computer system, a camera system, a scanner, or a navigation system.

A processor-based system 300, e.g., the computer system, may include a central processing unit (CPU) 310 (e.g., micro-processor), which can communicate with an input/output (I/O) device 370 via a bus 350. The central processing unit 310, a storage 320, a CD ROM drive 330, a port 340, and a RAM 380 may be connected to each other via the bus 350 to send or receive data to each other, and may process and output distance data to be obtained from the image sensor 360. The port 340 may be used as a terminal allowing a video card, a sound card, a memory card, and/or a USB card to be connected to the system 300 or as a communication port for data communication with other system.

According to example embodiments of the inventive concepts, the image sensor may be realized using chalcogenide, and thus, there is no necessity to use a Fabry-Perot cavity. Accordingly, it is possible to omit some process steps, e.g., a vacuumizing step or an inert gas injection step. As a result, it is possible to achieve simplification of the fabrication process, a reduction of fabrication cost, and miniaturization and densification of the image sensor.

Further, in the image sensor, the chalcogenide-containing first layer may form a junction in conjunction with a second layer containing doped silicon or doped germanium, and thus, widening a sensible wavelength range of the image sensor may be possible.

While example embodiments of the inventive concepts have been particularly shown and described, it will be understood by one of ordinary skill in the art that variations in form and detail may be made therein without departing from the spirit and scope of the attached claims.

What is claimed is:

1. An image sensor, comprising:
a first layer on a substrate, the first layer including a chalcogenide-containing material; and
a detection part connected to the first layer, the detection part configured to detect a variation in electric characteristics of the first layer, wherein the chalcogenide-containing material includes one of AₓB_{y}S_{1-x-y}, AₓB_{y}Te_{1-x-y}, and AₓB_{y}Se_{1-x-y}, where 0<x<1, 0<y<1, A includes at least one of Si, Ge, Sn, Pb, Al, Ga, In, Cu, Zn, Ag, Cd, Ti, V, Cr, Mn, Fe, Co, and Ni, and B includes at least one of Sb, Bi, As, and P.

2. The image sensor of claim 1, further comprising:
an interposition layer between the substrate and the first layer, the interposition layer in contact with both the substrate and the first layer.

3. The image sensor of claim 2, wherein the interposition layer includes at least one of a reflection layer, a finite impulse response filter, and an isolation layer.

4. The image sensor of claim 1, further comprising:
an anti-reflecting layer on the first layer.

5. The image sensor of claim 1, wherein the first layer is spaced apart from the substrate by a cavity.

6. The image sensor of claim 5, wherein a thickness of a cavity between the first layer and the substrate is about one-fourth a wavelength of an incident light.

7. The image sensor of claim 1, wherein the detection part is configured to detect a variation in electric resistance of the first layer.

8. The image sensor of claim 1, further comprising:
a second layer between the substrate and first layer, the second layer including a material containing one of doped silicon and doped germanium,
wherein the first and second layers constitute a junction.

9. The image sensor of claim 8, wherein the detection part is connected to the second layer to detect a variation in electric current between the first and second layers.

10. The image sensor of claim 1, wherein the substrate includes a first surface and a second surface facing the first surface.

11. The image sensor of claim 10, further comprising:
an anti-reflecting layer on the first surface; and
the first layer on the second surface.

12. The image sensor of claim 10, further comprising:
an anti-reflecting layer on the second surface; and
the first layer on the first surface.

13. An image sensor comprising a first layer on a substrate, the first layer including one of AₓB_{y}S_{1-x-y}, AₓB_{y}Te_{1-x-y}, and AₓB_{y}Se_{1-x-y}, where 0<x<1, 0<y<1, A includes at least one of Si, Ge, Sn, Pb, Al, Ga, In, Cu, Zn, Ag, Cd, Ti, V, Cr, Mn, Fe, Co, and Ni, and B includes at least one of Sb, Bi, As, and P.

14. The image sensor of claim 13, further comprising:
an interposition layer between the substrate and the first layer, the interposition layer in contact with both the substrate and the first layer.

15. The image sensor of claim 13, further comprising:
a second layer between the substrate and first layer, the second layer including a material containing one of doped silicon and doped germanium,
wherein the first and second layers constitute a junction.

16. The image sensor of claim 13, further comprising:
an anti-reflecting layer on the first layer.

17. The image sensor of claim 13, wherein the first layer is spaced apart from the substrate by a cavity.

18. An image sensor comprising:
a first layer on a substrate, the first layer including one of doped silicon and doped germanium; and
a second layer on the first layer to form a junction, the second layer including a chemical compound containing at least one of S, Se, and Te.

19. The image sensor of claim 18, further comprising:
an interposition layer between the substrate and the first layer, the interposition layer in contact with both the substrate and the first layer.

20. The image sensor of claim 18, wherein the first layer is spaced apart from the substrate by a cavity.
